(19) United States
(12) Patent Application Publication
(10) Pub. No.: US 2013/0180450 A1
(43) Pub. Date: Jul. 18, 2013

(54) MULTIFUNCTIONAL MANUFACTURING PLATFORM AND METHOD OF USING THE SAME

(71) Applicants: Ray Hamilton, Swainsboro, GA (US); Tracy Becker, Swainsboro, GA (US)

(72) Inventors: Ray Hamilton, Swainsboro, GA (US); Tracy Becker, Swainsboro, GA (US)

(21) Appl. No.: 13/625,312

(22) Filed: Sep. 24, 2012

Related U.S. Application Data
(60) Provisional application No. 61/537,868, filed on Sep. 22, 2011.

(51) Int. Cl. H05K 13/00

(52) U.S. Cl. CPC H05K 13/00
USPC 118/697

(57) ABSTRACT

A single, flexible, robust and low rate capable manufacturing platform that may be associated with caseless munitions firing circuits, nano and microelectromechanical (“NEMS” and “MEMS”) devices, and/or fractal antennas is described. The platform may be designed for extensive research and development in printed electronics, 3D thermo-plastics and low melt metal casting, light machining, and other processing operations necessary for the integrated fabrication of various components, such as caseless munitions components. The platform may be used in a remote location.

### CROSS REFERENCE TO RELATED APPLICATIONS

This application claims priority to U.S. patent application Ser. No. 11/711,494, entitled Multifunctional Manufacturing Platform and Method of Using Same, naming inventor Tracy Becker and filed Feb. 24, 2010, which claims priority to U.S. Patent Application No. 61/208,479, filed Feb. 24, 2009.

### FIELD OF THE INVENTION

The instant invention relates to the field of manufacturing platforms, and in particular to platforms for and methods of integrating multiple functionalities in the manufacture of products, particularly including nano and micro scale products.

### BACKGROUND OF THE INVENTION

In the manufacture of certain products requiring nano and micro scale components, such as fractal antennas and caseless munitions firing circuits, the majority of commercial platforms available today are designed and built for a single functionality. For example, a platform including a machine or tool designed for electronic printing is not additionally suitable for three dimensional thermoplastic printing, and vice versa. This means, in the aforementioned example, that in the development of products that require both electronic printing and three dimensional thermoplastic printing, two separate machines on separate operating platforms are required. Needless to say, this requirement increases costs and manufacturing time, while reducing quality, by necessitating that such products pass through multiple manufacturing environments, thus exposing the products to increased possibility of negative quality effects by passing through multiple, exceedingly expensive machines.

For example, each separate machine may be built by a different commercial entity, and decisions in the production and manufacturing tolerances of such separate machines are often tailored to only each designing entity's prime market, expertise, national affiliation, costs, and/or perceived customer need. This may cause each machine to require a different axis configuration, differing precision levels, and/or differing controls and user interfaces. Further, these differing controls and interfaces require different manuals, repair part inventories, and/or user training. In fact, significant increases in the training for both operators and service personnel are quite likely required due to the aforementioned differing controls and interfaces. It should be appreciated that not only do different tolerances and the like cause a lower quality output, but additionally that the opportunity for human error also significantly increases with differences across prototyping or production machines. These factors inevitably lead to incorrect, improper or low quality part manufacturing, and may additionally lead to, for example, equipment damage. Such unacceptable results are costly in both raw materials and replacement parts, as well as in lost time.

Another problem with multi-platform, multi-machine manufacturing environments is that any transferring of a product under production, prototyping or development requires additional and valuable time, and is prone to misalignment and/or contamination. Such transfers would include removing the item for inspection and verification of numerous processes in a line of assembly, for example. Moreover, to build complex devices such as the antennas and firing devices mentioned above, units under production need to be removed from one machine process, inspected, and mounted in the next machine at a highly precise location and alignment. This unquestionably increases the failure rate due to damage and contamination. Thus, whether performed manually or robotically, transferring products, or parts thereof, in production, prototyping or development is likely to significantly increase the risk of deforming, contaminating, or otherwise damaging the product.

Further still, there is no available multifunctional platform that is ruggedized and functionally available to perform in-field, or in theater, part or product production, in part due because the current art requires multiple machines to produce complex products such as those discussed herein. For example, in military applications, a warfighter may need to perform manufacturing steps when away from a specialized and/or protected laboratory facility. In the current art, the warfighter would require duplicate, multiple sets of platforms to finalize or perform partial manufacturing when away from the laboratory, an insurmountable problem curable only by a rugged, multi-functional single platform with the integrated tooling and remote and local interfacing necessary to complete the multi-faceted manufacture of the product in the field.

Therefore, a need exists for a multi-tool, multi-functional, remotely or locally computer-controllable platform that is designed for simple replication of multi-step manufactured processes, and that is suitable for both laboratory and in field use.

### SUMMARY OF THE INVENTION

A single, flexible, robust and low-rate capable but scalable manufacturing platform that may be associated with caseless munitions firing circuits, nano and microelectromechanical (“NEMS” and “MEMS”) devices, and/or fractal antennas, by way of non-limiting example, is described. The platform may be designed, used, and/or implemented, for example, to perform extensive research and development, and/or prototyping, in printed electronics, 3D thermo-plastics and low melt metal casting, light machining, and other processing operations necessary for the integrated fabrication of various components, such as caseless munitions components. The platform may be used in a remote location.

Thus, the present invention provides a multi-tool, multi-functional, remotely or locally computer-controllable platform that is designed for simple replication of multi-step manufactured processes, and that is suitable for both laboratory and in field use. The present invention has at least military, commercial, industrial and research applications.

### BRIEF DESCRIPTION OF THE FIGURES

Understanding of the present invention will be facilitated by consideration of the following detailed description of the embodiments of the present invention taken in conjunction with the accompanying drawings, in which like numerals refer to like parts and in which:

FIG. 1 is an exemplary illustration of a tool-changing platform, according to an aspect of the present invention;

FIG. 2 is an exemplary embodiment of a single integrated platform suitable for performing multiple tool-based functionalities, according to an aspect of the present invention;

FIG. 3 is a block diagram illustrating exemplary processes provided according to the present invention;

FIG. 4 is an exemplary embodiment of a gantry and tooling mount drive according to the present invention;

FIG. 5 is an exemplary illustration of the drop-on-demand functionality of the present invention;

FIGS. 6A and 6B are exemplary embodiments of a materials extruder according to the present invention;

FIG. 7A and 7B are exemplary embodiments of the pick and place functionality of the present invention;

FIG. 8 is an exemplary embodiment of the laser soldering functionality of the present invention;

FIGS. 9A and 9B are exemplary embodiments of the quality control functionality of the present invention; and

FIG. 10 is an exemplary embodiment of a tool-changing platform, according to an aspect of the present invention.

### DETAILED DESCRIPTION OF THE PREFERRED EMBODIMENTS

It is to be understood that the figures and descriptions of the present invention have been simplified to illustrate elements that are relevant for a clear understanding of the present invention, while eliminating, for the purpose of clarity, many other elements found in typical manufacturing platforms. Those of ordinary skill in the art will recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art. Furthermore, the embodiments identified and illustrated herein are for exemplary purposes only, and are not meant to be exclusive or limited in their description of the present invention.

The present invention relates to a multi-tool and/or multi-axis, precision positioning, computer controlled platform capable of multiple material delivery, material curing methods, and in-situ inspection capabilities, among other functionalities. The present invention may be ideal for processes, methods and manufacturing of various nanotechnology based products, and may be suitable for both research and development and prototyping at low production costs. The platform may be programmable to automatically change between print heads, material extruders, inspection devices and other equipment necessary to produce complex devices in a single setup and/or on a single platform. The platform may be locally or remotely computer controlled, such as over at least one wired or wireless telecommunications or satellite network, using an easy-to-use, module-based user interface (UI). The UI may may further include a common user interface across platforms, and/or a single motion control system. The single platform design of the present invention minimizes item damage and loss of time due to item transfer(s). The platform may include “drop-on-demand” and 3D thermo plastics printing functionality, as well as robotic gripping functionality, such as using a robotic arm with highly accurate and gentle ball-bearing based pincers, for placement and transfer of intricate parts and tools across the platform.

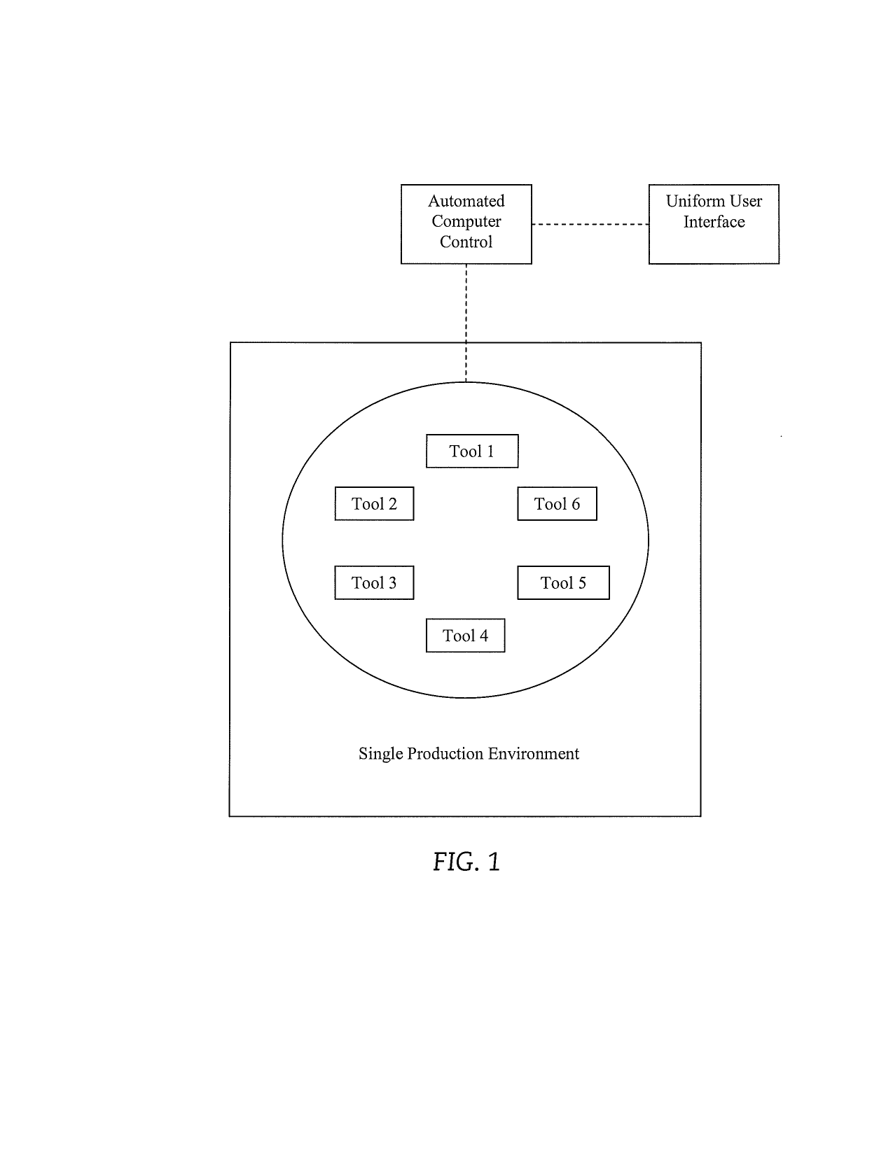

As mentioned above, the platform of the present invention may provide numerous functionalities and features. For example, the platform may provide automated ‘tool’ changing, such as multi-tool manufacturing turret, gantry, or robotic slide that may include, for example, ready access to one or more gas inlets, outlets, vacuums, printheads, nanoprintheads, motors, and manufacturing tools, such as sterile and/or remotely manipulable pincers, drivers, guns, injectors, and the like, as shown in FIG. 1, such as to allow for unattended operation. The present platform may be roll-to-roll production capable.

The platform may be network aware of the aforementioned telecommunications and/or satellite network, such as for remote operation and protected, secure accessibility from the internet, an intranet, an extranet, a cellular network, or a dedicated network, for example. The platform may, for example, include an in-situ inspection camera for local or networked-remote monitoring, UV curing light source, heat curing system, and/or a solid and vacuum table, and/or may have internal product movement capabilities, such as in embodiments wherein the product moves within the platform, rather than the tooling sliding, rotating or otherwise moving as discussed hereinabove. The substrate table of the platform may be adjustable in a rotary motion, such as discussed above with regard to a turret, for aligning existing products, or in-process products, requiring modifications or further processing. The substrate table of the platform may similarly be adjustable in the x and y axis, such as discussed hereinthroughout with regard to a robotic slide, for aligning existing products, or in-process products, requiring modifications or further processing. The platform may also be different OEM head capable and include a standard programming interface. Such a standardized interface may be suitable for mechanical as well as electronic options and accessories. The platform may utilize ID and OD articulated movement of the product substrate, including all robotic capabilities, such as for printing on missile nose type shapes, by way of non-limiting example.

The platform may combine rapid prototyping and lower-scale production technologies, and further be suitable for incorporating future capabilities and features used in current and developing research. The platform preferably provides the user numerous additional capabilities on a common physical base and with a common control UI, thereby reducing training and maintenance costs and significantly decreasing the “lab-to-field” time currently available from non-integrated, multiple platforms.

In particular exemplary embodiments, the present invention may be used for rapid fielding of nanotechnology and other advanced technologies, including in-field development of such technologies. The present invention may further enhance development of materials and methods for advanced devices.

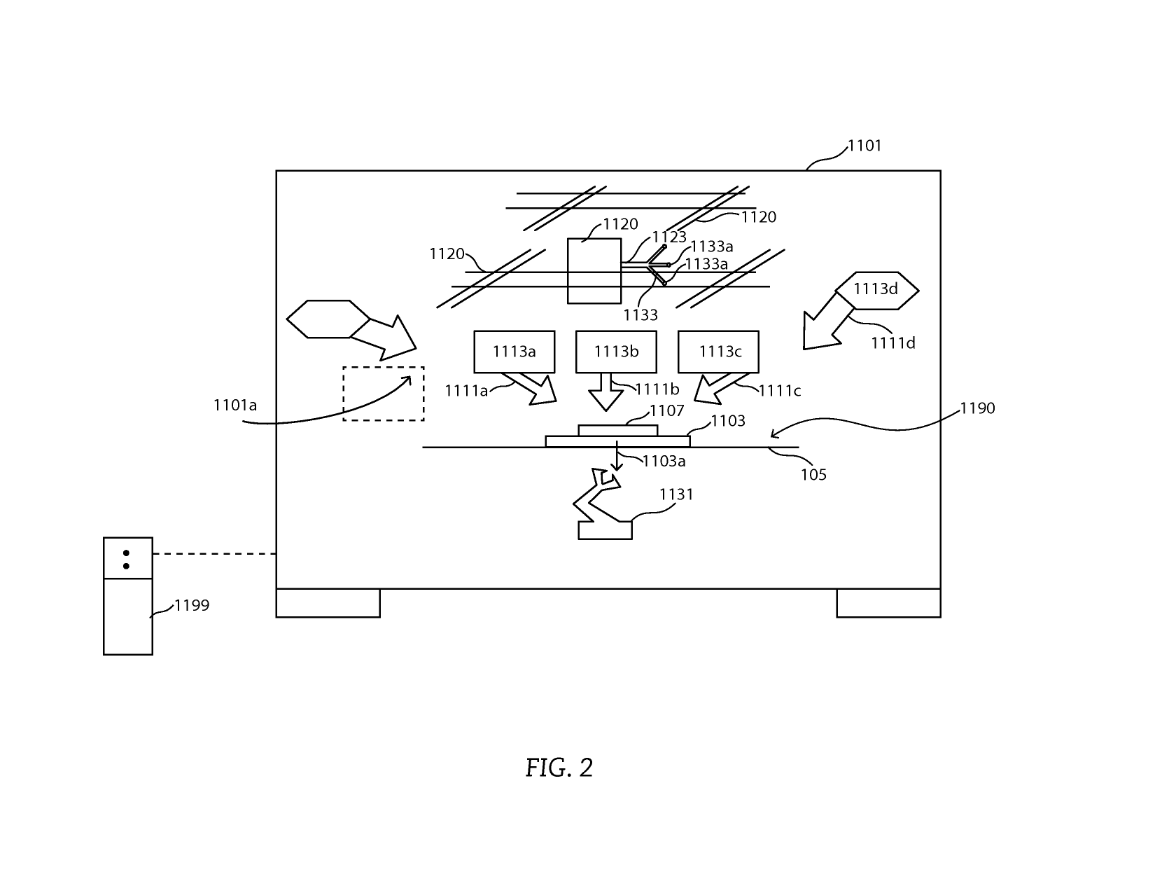

More particularly, and by way of non-limiting example, the present invention may perform various tasks on a work item, such as a substrate, without exposure of the work item to external contaminants and/or without manual intervention to switch tools that apply particular processes to the work item. A work machine according to the present invention is illustrated in the example of FIG. 2. As illustrated, the machine 1101 may include a base, such as a table, such as a vacuum base 1103 on a vacuum table 1105, onto which the work item 1107 may be placed for exposure to processes 1111a, b, c, d. The work item 1107 may be, for example, a blank substrate akin to an unmodified PC board, and the work item 1107 may be subjected to a vacuum 1103a by vacuum base 1103. In optional exemplary embodiments, vacuum base 1103 may have adjacent thereto, such as vertically thereunder, a robotic arm for repositioning of vacuum base 1103 and/or work item 1107. Likewise, in optional embodiments, vacuum base 1103 may be removed in favor of robotic arm 1131, such as to provide additional axes for positioning work item 1107. Adjacent to vacuum base 1103 may be a variety of tools 1113a, b, c, d correspondent to processes 1111a, b, c, d and for applying the processes to the work item 1107. In the illustrated embodiment, the tools may be at the “front” 1101a of machine 1101, and may be suspended above and lateral to vacuum base 1103.

Adjacent to the tools 1113a, b, c, d may be multi-axis gantry 1120. Multi axis gantry may be formulated such that tool mount 1123 may move along the gantry in at least the x, y, and z axis with respect to the plane formed by machine front 1101a. Tool mount 1123 may thereby move across the grid formed by the tools 1113a, b, c, d to access a respective one of the tools, such as in order to move the tool down into position in relation to work item 1107 to perform a correspondent one of processes 1111a, b, c, d on work item 1107. That is, in a preferred embodiment, work item 1107 remains stationary, while gantry 1120 accesses tools 1113a, b, c, d and moves such tools into position to perform processes 1111a, b, c, d on work item 1107.

In an embodiment, tool mount 1123 includes, in association therewith such as extending laterally therefrom for access to the tools on the front 1101a of machine 1101, a plunger 1133. Plunger may include, by way of non-limiting example, a plurality, such as three, spring loaded ball bearings 1133a. Further, in such embodiments, each tool may include a female mate to the plurality of ball bearings 1133a. Thereby, plunger 1133 may be extended from tool mount, such as by gantry 1120, inserted into a respective one of tools at which time spring loaded ball bearings 1133a may spring open to securely grasp tool, and gantry may then spin tool mount, and thus plunger 1133, over work item 1107. The tool grasped may then be positioned by gantry to perform the process correspondent to the grasped tool, as referenced above. As such, tool mount may robotically or mechanically extend plunger 1133, and may further mechanically or robotically actuate ball bearings 1133a.

As such, each respective tool with respect to each respective process may be used to carry out a desired process, and may then be replaced at the front of machine 1101, such as after use, to the same location from which the tool was grasped. Thereby, the machine is enabled to consistently access tools without unnecessary processing or errors. Of course, each tool may be encoded, such as using RF tagging or bar coding, to be read by a reader associated with tool mount and/or plunger 1133, to thereby avoid unnecessary processing or errors in insuring consistency in accessing the correct tool for a desired process. In such an embodiment, tool location may remain consistent after use, or tools may be arranged for improved ergonomic use before and after each use.

Thereby, the present invention performs processes on work item 1107 without moving work item 1107, unlike the available art, and without placement of work item into multiple machines to allow for independent processes, unlike the available art. These processes may be numerous, as discussed hereinthroughout, and may necessitate different toolings to be associated with tool mount 1123. For example, a particular process may be layering of a paste, and consequently an auger may be associated with a paste tube, and further may be associated with a motor to cause the auger to compress the paste tube. Such a tool (i.e., the combination of the paste tube, auger, and motor) may be obtained to tool mount 1123 by gantry 1120 to allow layering of the paste to work item 1107. Other exemplary tool interactions with work item 1107 are discussed hereinthroughout.

The present invention provides these multiple tool interactions in a highly accurate, efficient manner, such as to within 0.0002 inches of tolerance. This accuracy and efficiency stems, in part, from the stationary, maintained position of the work item 1107, to allow for interaction of item 1107 with any of the various tools for various processes, with inspection, with curing, and the like. Further, the machine 1101 may be heavily weighted, and may be heated prior to use, to further insure high accuracy and no variability of the machine or its base during processes.

Further, the chamber 1190 in which the various processes discussed herein are applied to work item 1107 may be environmentally controlled, and capable of being heated, cooled, evacuated, pressure-modified, or the like, either for processing or field testing of work item 1107. Likewise, the chamber may be subjected to highly accurately regulated gas flow, such as for inert or process-related gases.

Moreover, gantry and/or tool mount may have high grade positioning capability, such as using high grade linear ball screws, and positioning of tools may be subjected to redundant positioning and/or feedback to insure high accuracy. For example, high accuracy glass scales may be used to insure precise positioning. Further, motors to position gantry and/or tool mount may provide positional feedback, such as using a tachometer, by way of non-limiting example. Further, servo/motors used in the instant invention may be tuned, either mechanically or using tuning software, such as the process control software discussed herein. Of course, the precision of the present invention may be intentionally varied, such as to allow for offering of a high precision, higher cost machine and a lesser precision, lower cost machine.

As discussed hereinthroughout, the machine 1101 of the present invention may preferably be connected, such as via wire, wireless/RF/infrared, or like communicative connections, to one or more computing processors executing computing code from one or more computing memories which, upon execution, causes machine 1101 to perform the various steps, functions, processes and methods discussed herein. As discussed herein, such computing code 1199 may track the position of the tools, gantry, plunger, work item, and the like, may monitor status, such as positional statuses, environmental statuses, vacuum table or robotic arm status, or the like (such as through connection to one or more sensors physically associated with machine 1101), may provide or accept one or more control models for the performance of the processes associated with the tools, and/or may provide feedback to optimize performance of the processes discussed herein, by way of non-limiting example.

The control software 1199 may be or include modular control, such as based on discrete models of each tool and each process, thereby allowing for “plug and play” of each individual process into a broader method to obtain a particular work item 1107. Thereby, for each performance of a process by a tool, a user may simply enter a desired end point for the tool, and/or when the tool is to perform its process, in a given method for a given work item 1107, and the model for that tool in software 1199 may automatically execute performance of that process for that tool to that end point or at that time for a given time.

Further, software 1199 may accept process inputs from a user of machine 1101, or may recommend processes, an ordering or processes, times of end points for processes, or the like upon receipt from the user of a desired outcome of work item 1107. Moreover, in such embodiments, the user may purchase or otherwise obtain only those modules for software 1199 necessary to perform the required method to obtain particular work item 1107. The presence of only required modules in or in association with software 1199 thus improves efficiency, limits storage needed, and eases processing load, in use of machine 1101. Likewise, connection of the processor(s) associated with the software to a network may allow for remote storage of the modules associated with software 1199, whereby the machine 1101 may obtain from the remote location those modules needed for an given method. As such, the modules may be, in essence, macros running locally or remotely to machine 1101.

Further, the aforementioned feedback may allow for the use, by software 1199, of data points obtained in performing processes to improve such processes. Thus, the data points in performing processes may be stored in the memory associated with the software 1199, and/or may be stored in memory on-board each tool. Similarly, software 1199 may, in exemplary embodiments, serve only to provide a master task list, and the modules discussed herein may be on-board each tool.

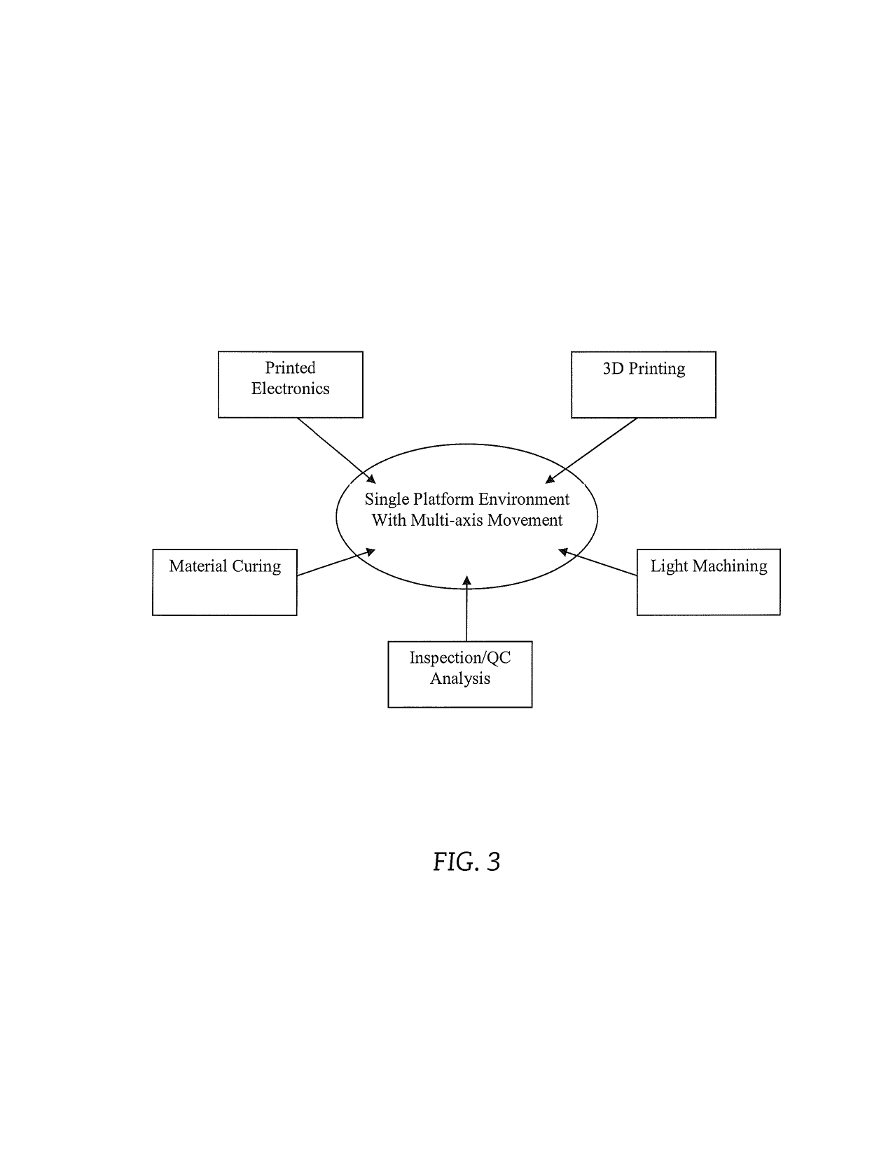

The present invention thus provides, in specific exemplary embodiments, a single, flexible, robust prototype and low production rate capable manufacturing platform that may be associated with caseless munitions firing circuits, nano and microelectromechanical (“NEMS” and “MEMS”) devices, and fractal antennas, by way of non-limiting example. As shown in FIG. 3, the platform may incorporate the tools and programming illustrated in FIGS. 1 and 2, such that it may be designed for extensive research and development in printed electronics, 3D printing in thermo-plastics and/or low melt metal casting, light machining, material curing, inspection and/or quality control analysis, along with other processing operations necessary for the integrated fabrication of various components, such as caseless munitions components and fractal antennas, by way of non-limiting example. The platform may thus be used, such as via at least one networked connection, in a remote location for rapid in-field development and deployment.

The platform may also allow for configuration adaptability to accommodate the manufacture of multiple types of products and/or component parts to eliminate the need to purchase a new machine or manufacturing platform each time a new part must be manufactured. In addition, interfacing with the present invention changes very little, if at all, between differing configurations and may thus allow for a predefined and limited amount of user operational training. Thereby, the present invention provides for the rapid prototyping and/or manufacturing of products that may be suitably produced on a platform of a particular size.

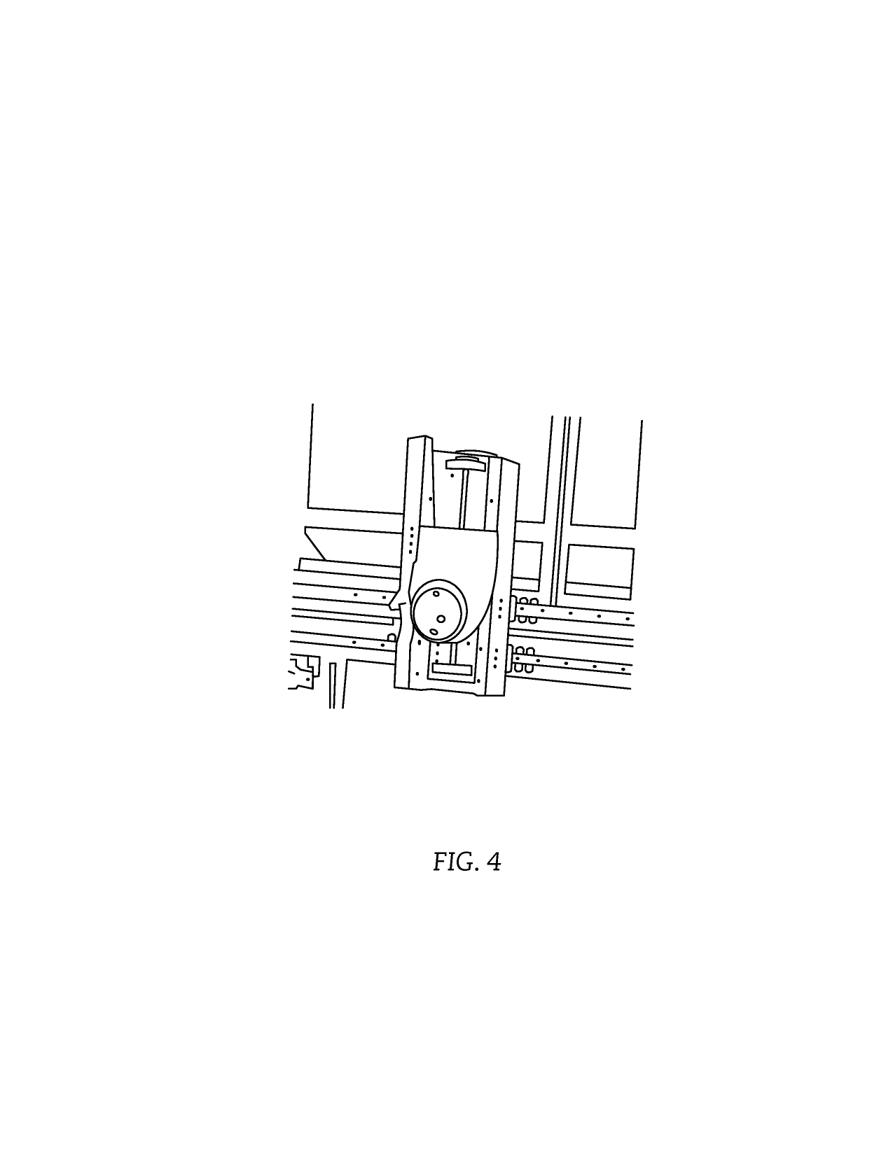

An exemplary drive mechanism for controlling a base tool plate of the present platform is illustrated in FIG. 4, and this drive mechanism may allow for the production of goods having at least of the 0.0002 inch tolerance and repeatability discussed herein. The present invention may include a 18″×24″ vacuum table or platen on the machine. Overall, the working envelope of the present invention may allow parts to be made that are 8 inches high by 18″×24″, or smaller, for example.

As mentioned above, the platform of the present invention may include electronic printing functionality. Printed electronics involves accurate depositing of functionalized inks, such as nanoscale silver, gold and copper, for example, on a variety of substrates, including flexible substrates, to create electrical circuits and components. This process is cheaper and greener then conventional electronics, and provides for significant reductions in inventories.

The platform of the present invention may incorporate multiple axis movement for electronic printing, such as in a Cartesian pattern. In an exemplary embodiment, six axis may be computer controlled. It should be appreciated that the platform may inactivate or otherwise utilize fewer axis of movement, depending on the devices in manufacture and other environmental circumstances.

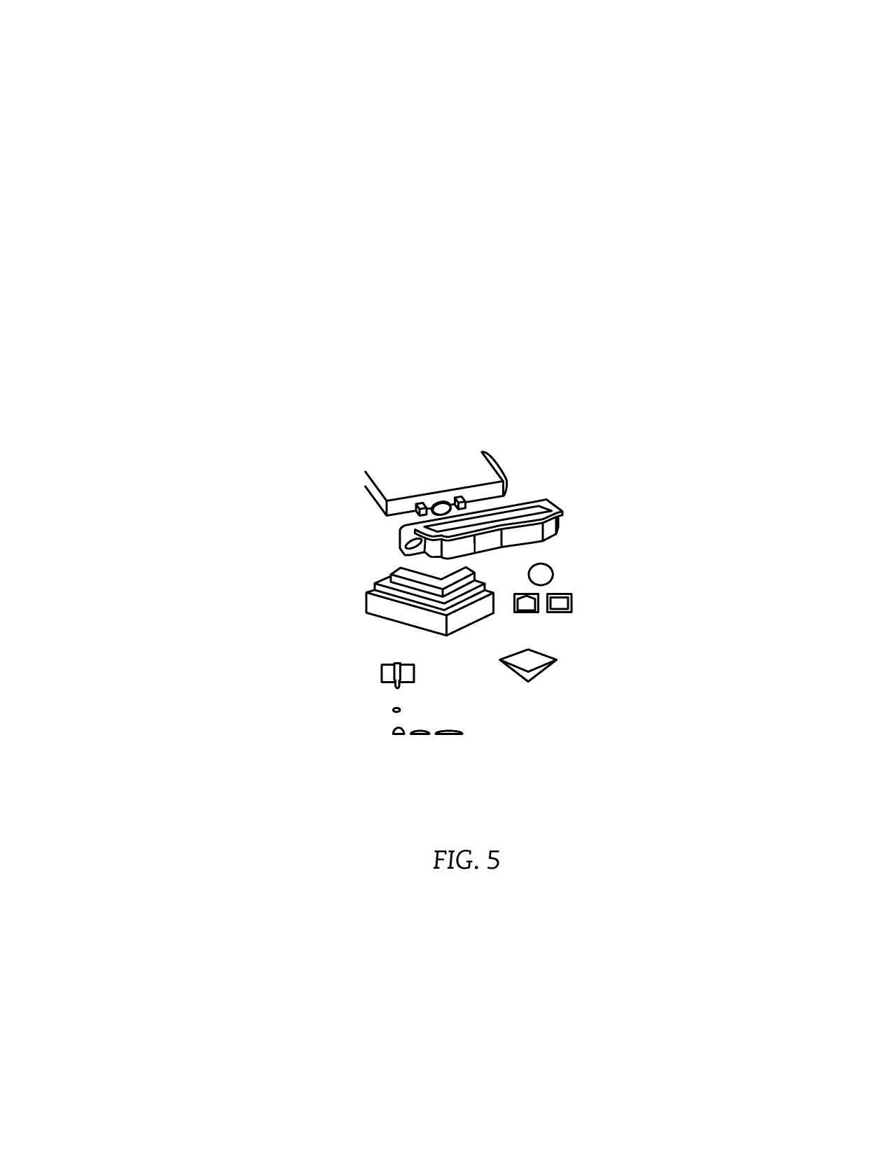

In one specific exemplary embodiment of the present invention, as illustrated in FIG. 5, the platform may include “drop-on-demand” electronic printing. Drop-on-demand printing allows users to precisely control the placement of the ink on the substrate, and with minimum effort to change the design to accommodate new concepts or ideas. Drop-on demand is comparable to computer numerical controlled (CNC) machine tools used in the metal cutting industry. By further example, the printing component may include a three axis Cartesian system under computer controlled movement commands. Additional axis may be included, both powered and/or manual, depending on any particular application. The platform of the present invention may include the integration of differing print heads, as well as six axis control of platform movement, making the platform suitable for multiple styles of drop-on-demand printing, such as thermal, piezoelectric, electrostatic and aerosol methodologies. The print heads used with the present invention may vary greatly and are not limited by size or resource demands given the modular nature of the present invention. For example, a print head having sixteen (16) jets may be used in one configuration while a print head having one hundred and twenty-eight (128) may be used for a different configuration. Similarly, multiple head sizes may be used simultaneously by the present invention to maximize efficiencies

By way of further example, U.S. Pat. Nos. 6,503,831 and 6,713,389 (issued to Speakman on 7 Jan. 2003 and 30 Mar. 2004 respectively) describe drop-on-demand printing of inks for electronic circuit elements. Curing (or solidification) of printed material may be achieved using conventional drying and/or radiation-enhanced drying or curing. The curing process may include radiation-induced cross-linking of organic materials. In particular, Speakman describes a radiation source close to the nozzle (on the print head) that can be used to treat deposited material either before, during or after deposition. One of the advantages of irradiating in-flight is to partially cure the material before deposition and thus reduce dot sizes before impact on the substrate. In general, the term “cure” with relation to polymer materials is used to refer to solidification of the deposited material.

Similarly, Mogensen in U.S. Pat. No. 6,697,694 (issued on Feb. 24, 2004 and incorporated herein by reference) describes a method for printing flexible circuits by printing layers of materials using techniques that include drop-on-demand printing. Mogensen describes a method and apparatus whereby materials are dispensed on a flexible substrate in a predetermined pattern using a dispensing unit which can plot patterns using motions in the x, y and z axes relative to the substrate. Printed material is then cured by a separate curing unit, which can also be moved relative to the substrate. Layers may be formed by successively printing and then curing each layer. The described curing unit may either provide UV, infrared, or gamma radiation. Alternatively, curing can be achieved using heating methods.

Drop-on-demand printing may also be used to deposit organic and/or inorganic nanoparticle materials that can be cured to form conductive elements. In these cases, the curing process results in the nanoparticles sintering or fusing to form conductive elements which have a lower resistance. In particular, curing of metal nanoparticle films may be achieved by heating the printed inks to temperatures of 150 to 200.degree. C.

For example, the drop-on-demand printing capabilities of the present invention may allow for the deposition of nano-silver and copper particles which may be used in the creation of flexible and low-cost printed circuits and/or components. For example, the present invention may allow for the drop-on-demand printing of photo-voltaics, touch screens, and/or interconnect wiring. Similarly, the production of bridgehead circuits for energetic ignition and caseless munitions intended to have NEMS or MEMS devices as a payload may thereby be fabricated. Fractal antennas may also be produced by printed electronics. The fractal antennas may be production ready once testing is successful. New, improved or replacement antennas may then be easily reproducible on a duplicated platform either in-theater or in factory production.

The platform of the present invention may further include the aforementioned 3D printing functionality for the printing of thermoplastics and creation of full 3D models in a relatively rapid time frame. The process consists of sequential printing of layers of extruded plastics to create the model or item. This capability is critical to create complex physical models that can be used in caseless munitions in both the thruster design and NEMS/MEMS mounting.

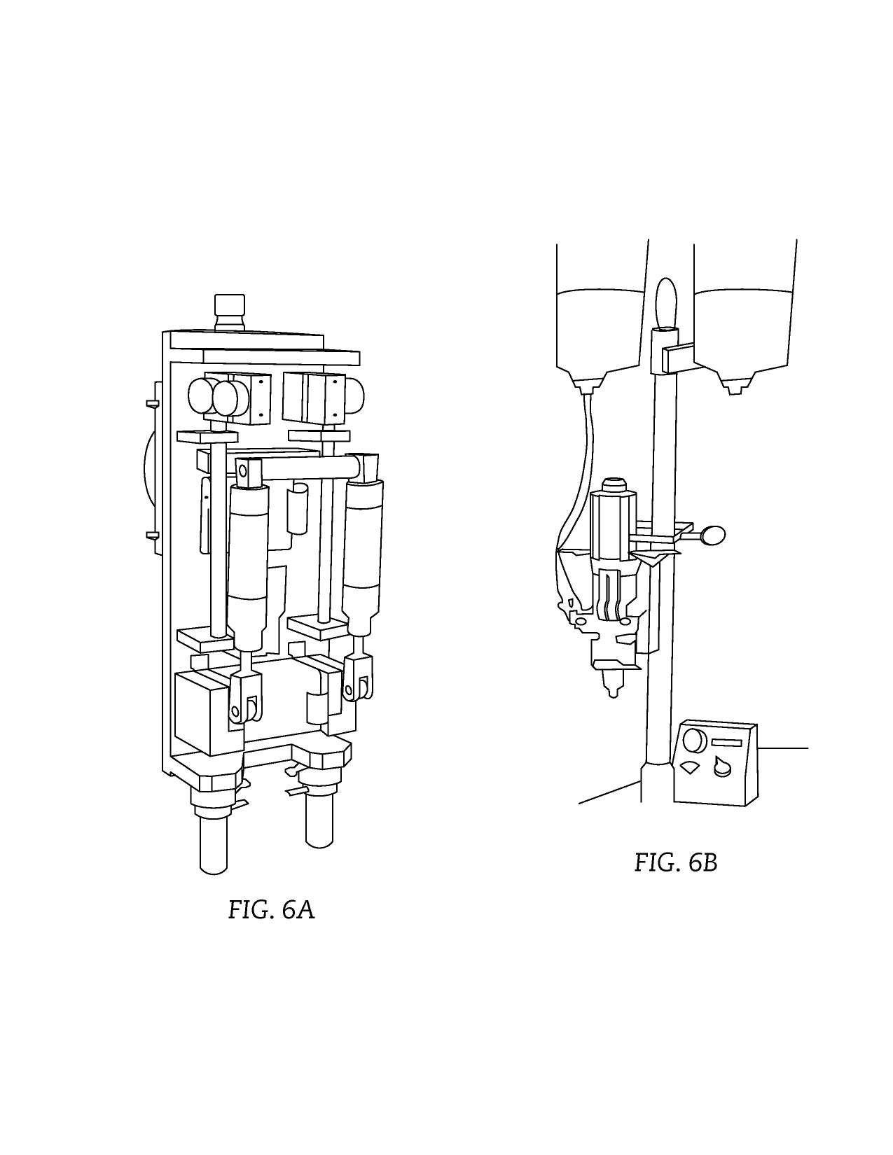

As illustrated in FIGS. 6A and 6B, the present invention may include a self-contained material extruder which may include, for example, a motor controller, air cylinders used in the feed process, motor drive for the reversal of feed, and/or at least one heated nozzle. The extruder is preferably mounted on the tool plate for use and may be one of the multiple tools available for use by the present invention.

The exemplary extruder used with the present invention includes the delivery of continuous materials with a digital specification being imposed by external logic. The fabrication method is preferably additive by depositing and/or bonding amorphous materials together in a way that results in a three-dimensional structure. Both the necessary computer control systems and building substrates may be remote from the extruder. The substrates, which may be powders and/or liquids and may include at least one binder may be remotely delivered to the extruder by a delivery tube, for example, from a reservoir system, such as illustrated in FIG. 6B.

As is well known in the art, most existing assemblers build three dimensional structures by dispensing small amounts of one or a plurality of different materials as droplets of very precise size at very precise locations. The present invention may use a variety of different extruder configurations, thus allowing for various methods of construction to be employed. In an exemplary method, a component may be constructed by depositing a first layer of a fluent porous material or porous solid with a binder material being deposited to selected regions to produce a layer of material. A second method consists of incorporating a movable dispensing head provided with a supply of material which solidifies at a predetermined temperature or when exposed to light or UV light.

Alternative deposition methods may include the use of an extruder using at least one filament at a desired position that, when heated, converts a portion of the filament to a flowable fluid that is solidified in the desired building position. Another method may comprise fabricating a three-dimensional object from individual layers of fabrication material having a predetermined configuration. In such a method, successive layers are stacked in a predetermined sequence and fixed together to form the object. Refinements may include producing parts from two distinct classes of materials, where the first class of material forms a three-dimensional shape defined by the interface of the first class of material and the second class of material. Alternate methods of manufacture may be found in U.S. Patent Publication No. 20110076762 entitled “Articles Formed By Manufacturing Processes, Such As Three-Dimensional Printing, Including Solvent Vapor Filming And The Like” to Serdy et al (filed Oct. 6, 2010 and incorporated herein by reference).

The platform of the present invention may further include the aforementioned precision light machining functionality. Precision light machining is often required during mounting of a nano or micro -ink printed device. In certain exemplary embodiments, such precision light machining may include milling, drilling and tapping for connecting one layer of substrate to another, or for electronic component mounting of NEMS/MEMS devices. Additionally, because printed conductive inks often have irregular surfaces after curing that interfere with subsequent layer deposition in forming semiconductors, a polishing operation may be included in the precision light machining to correct the subject surface. Further, precision placement of NEMS/MEMS devices in larger construction, such as a munitions warhead, may be performed in an automated manner in any production environment. This is accomplished by robotics with precision ‘end-effectors’ or ‘fingers’ that transport the NEMS/MEMS device and properly place it, under programmed computer control, in its proper location. Because the platform provides such machining as integrated with the aforementioned functionalities, all in an automated format, the platform provides for low failure rates and low damage rates during production assembly.

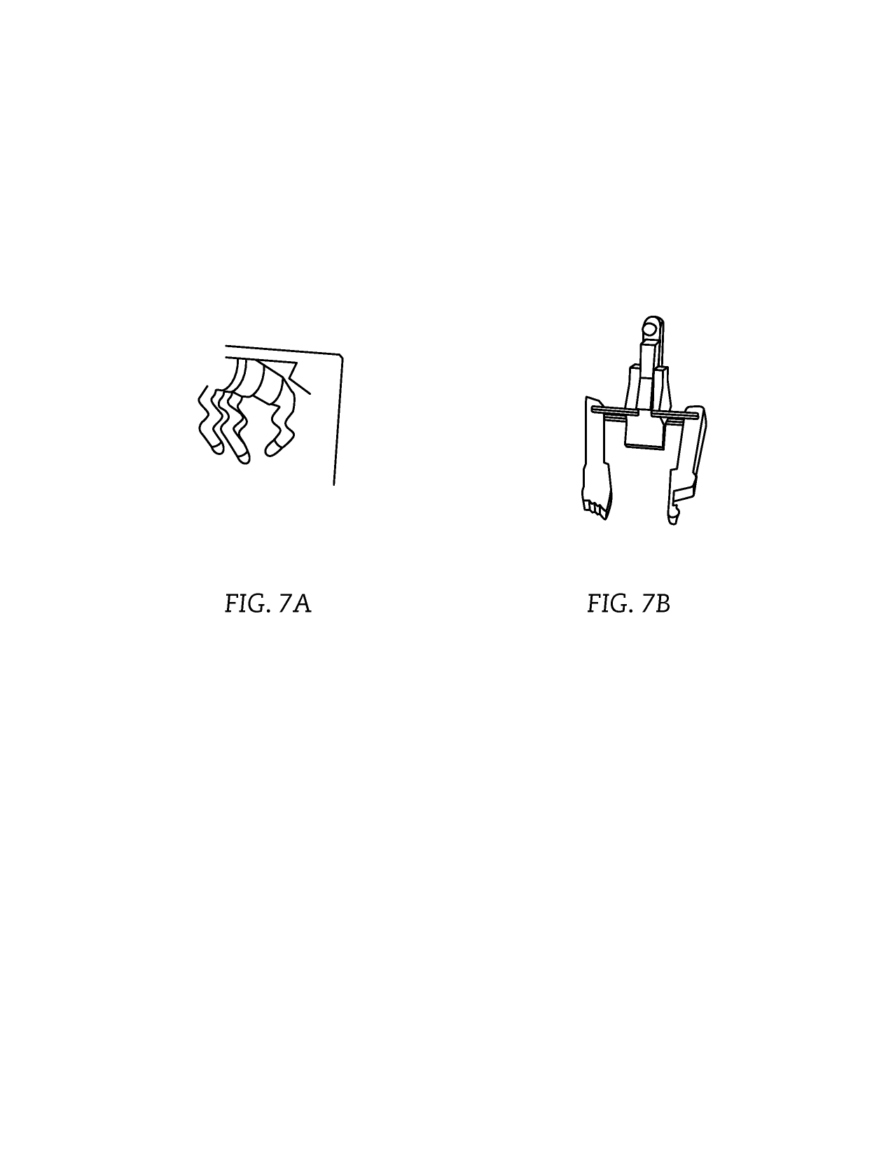

Further, as illustrated in FIGS. 7A and 7B and as discussed above, the platform of the present invention may include robotic/mechanical placement means which may enable the platform to handle and/or manipulate objects. Such robotics may take the form of a simplistic two pronged picker and/or a more complex “finger” based claw. The robotic means may take advantage of the vacuum, air and electrical controls provided at the tool plate.

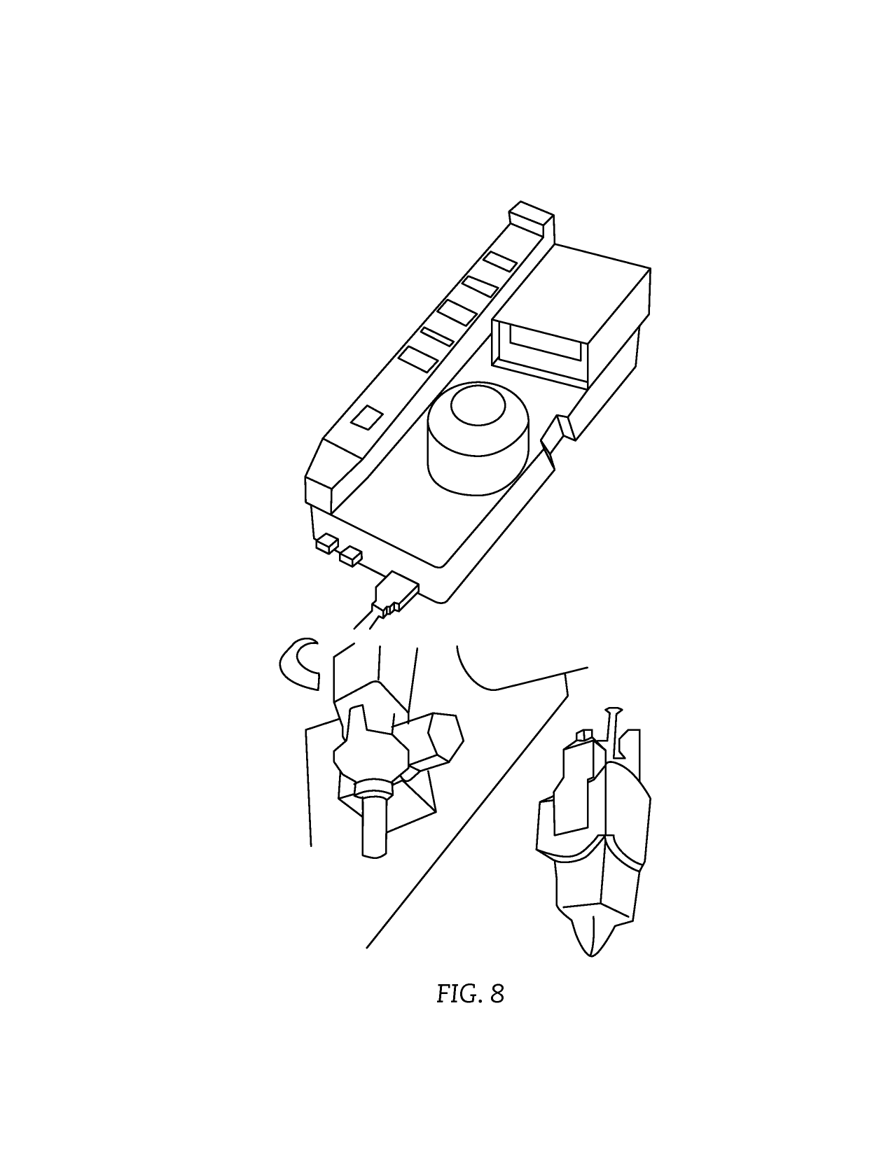

As illustrated in FIG. 8, the platform of the present invention may further include laser soldering functionality, or the use of lasers to heat automatically fed solder to connect NEMS/MEMS devices. This functionality provides a high precision and repeatable quality when performed in a computer controlled environment.

For example, a laser might be used to connect a diode in a circuit that was printed inside a 3D printed part that was earlier produced by the three dimensional extruder when attached to the tool plate. A soldering tool may utilize third party controllers and may be used for additional functionality, such as, for example, engraving, heat application to thermally sensitive materials, such as thermo plastics, and heat curing of micro-sized areas.

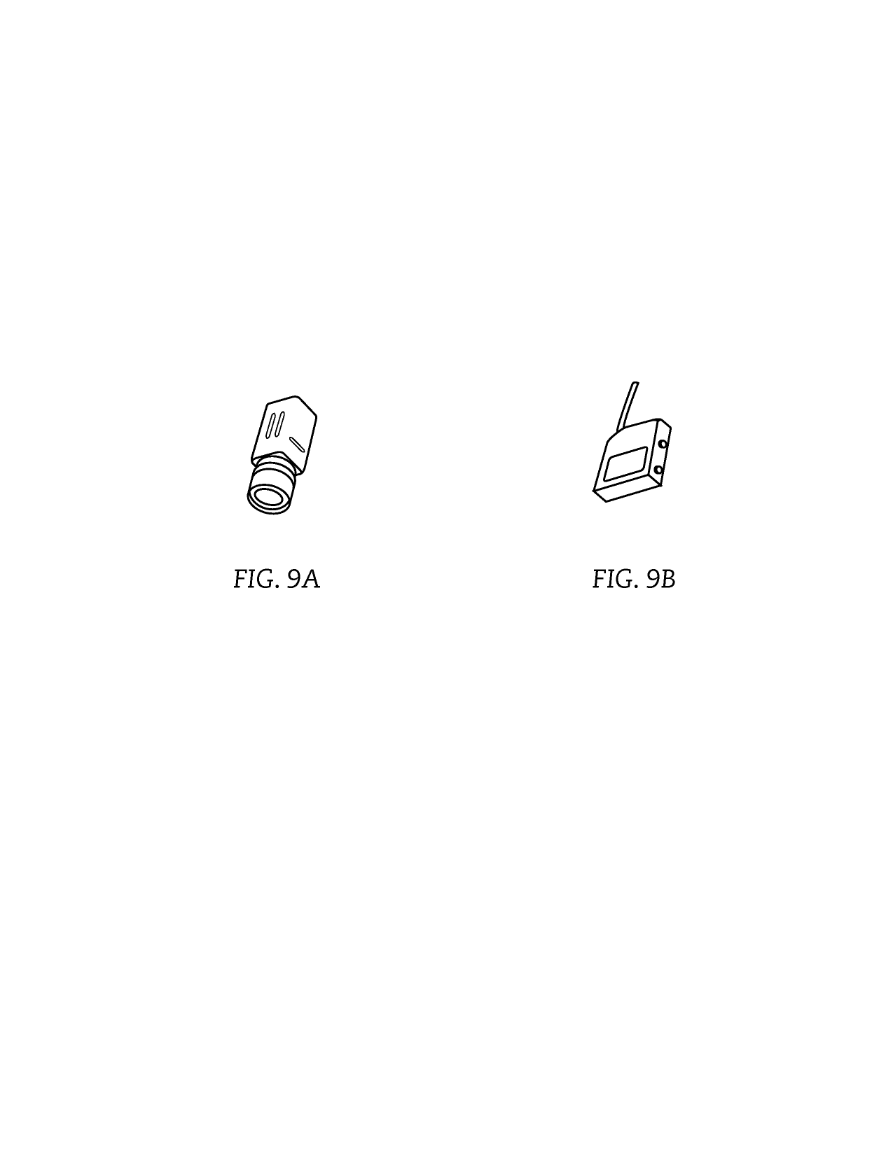

Because quality control is critical in an automated manufacturing environment, the platform may include video cameras, lasers and physical probing of the device during the process of manufacture, such as is illustrated in FIGS. 9A and 9B. This quality control functionality helps ensure correct dimensions and shapes of the manufactured devices, and the proper placement of sub devices or components within the manufacturing process.

More particularly, an ultraviolet curing source and/or video inspection/alignment camera and/or laser range finder may be used as a tool, and/or may be additionally mounted in the platform for automatic, scheduled, or manual use, such as in an on demand format. The laser may be employed to measure the height of the tool from the manufacturing process and/or the height of the manufactured work item 1107, for example. Such laser may similarly track the location of the tool relative to the working space. A camera may also be employed and may provide the user of the system a view of the work area and/or of the tool plate or tool storage area, for example. The camera may also provide infrared and near-infrared readings of work space activities, such as heating by a particular tool, to measure and control the manufacturing process being completed.

The platform of the present invention may further include duplication modeling functionality via the digitization of existing models for duplication, as well as the simplified modification of existing models. This process may include a physical probe or a range finding laser to map the existing item, and to convert the data to a computer model for duplication or modification.

The platform may also incorporate the aforementioned software 1199 in the form of a single human interface, which may be local or remotely networked, to control each of the integrated machine functionalities. The platform may further incorporate programmable capabilities either by manual input or by input of drawings or instructions developed by applicable design software. All drivers necessary for each integrated functionality may also be provided in formats conducive to each other and the underlying software operating systems.

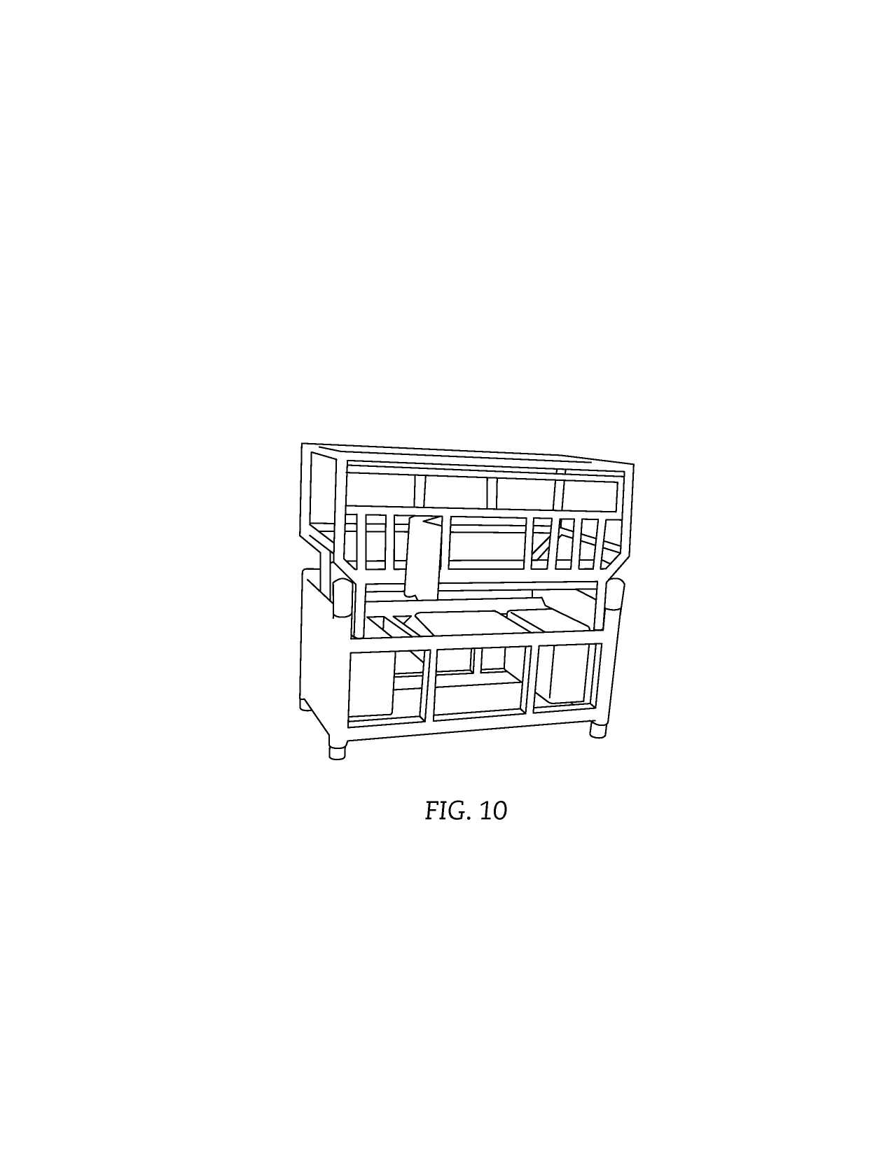

Thus, according to an aspect of an exemplary embodiment of the present invention, the base of the platform may be a high precision machine providing at least three to six or more axes of positioning specifically designed to accommodate the functionalities described hereinthroughout. In an exemplary embodiment, precision levels may be between approximately 0.0002″ or 0.004 mm positioning resolution. The platform ‘work table,’ as illustrated in FIG. 10, may be adjustable and/or provide a vacuum hold, such as to provide accurate alignment of existing item 1107 to be worked on. As discussed in more detail with respect to FIG. 2, the platform may also include a variety of tools accessible to the tool plate for automatic interchanging. In a non-limiting exemplary embodiment, the platform may have a selection of six (6) standard tools and a selection of up to six (6) “umbilical” tools (tools that require access to feed stock or other resources not directly attached to the platform, such as, for example, access to a drum of chemicals).

The platform work table may include the vacuum hold down, and/or a standard robot, such as for working on the ID of a missile nose, for example. It should be appreciated that some of the processes discussed herein rely on gravity which may significantly impact platform functionality. Each functional component may be supplied with unique wiring, vacuum, air and materials, such as inks, plastics, metal, and the like.

According to another aspect of the present invention, the platform controls and video feeds may be networked, either locally or wide area, or otherwise ‘network aware’ to allow for internet/intranet access for set-up assistance, maintenance, training and other uses. Therefore the present invention may be a remote controllable platform.

In practice, the processing of the specific exemplary embodiment producing caseless munitions needing NEMS/MEMS devices as a payload, functionalities performed by the platform may include printed electronics, fabrication of the body in using plastics and/or metal, deposition of an energetic material, precision placement of the NEMS/MEMS device. Thus, the present invention provides a single integrated platform to perform the functionalities of what would otherwise require five different machines, plus inspection stations and additional repeat operations.

In an example, in the processing of fractal antennas, functionalities performed by the platform may include drop-on-demand and 3D printing may for producing the necessary printed electronics. Fractal antenna design requires a high degree of design, manufacture, precision, testing and correcting for proper production. Using standard circuit board creation mechanisms, the process has historically been time consuming, expensive, and not environmentally friendly. The present invention provides for in-line production of the substrate or packaging for the antenna, and the end product is production ready when final testing proves successful. The present invention also provides for development of new, improved or replacement antennas on a duplicate platform in-theatre or in a factory to allow for seemless reproduction or partial completion in multiple locations.

As described hereinabove, each tool may be used alone on the tool plate and/or may be used with a plurality of tools. The number of tools used simultaneously may depend on the attachment space available of the tool plate. For example, the tool plate may accommodate any total weight in relation to the motors and actuators used with the platform and may, for example, not exceed ten (10) pounds a piece.

By way of example, a user of the platform in electronics may wish to create an electronic printing and simply “cut and paste” various tool applications together into a single tool cycle. For example, three dimensional printing may be combined with drop-on-demand in a single programmed cycle. Thus, the desired end product may be produced without the part being moved between machines and without the downtime necessary to move and/or introduce new tools or manufacturing capabilities, Similarly, a majority of the tool programming may be used between various applications to avoid the necessity of reprogramming and recalibration, for example, which may be needed on stand alone machines.

The platform may also be used remotely from the platform controls to facilitate the secure production of products at a remote and/or otherwise un-secure location. For example, the platform may be located for prototyping in the field of combat in a country remote from the location of the software controlling the platform. In one scenario, a soldier may require the replacement of a spring within an automatic weapon and may alert a controller of the platform of such a need. The remote user may, if communicatively connected to the platform, send instruction(s) to the platform for the production of the spring needed by the soldier. In this way, the instruction(s) sent to the platform may be encrypted and/or temporal such that after the spring, in this case, is manufactured, the platform may not again machine such a part without again receiving instructions from the remote user.

Those of ordinary skill in the art will recognize that many modifications and variations of the present invention may be implemented without departing from the spirit or scope of the invention. Thus, it is intended that the present invention cover the modification and variations of this invention provided they come within the scope of the appended claims and their equivalents.

1. A single integrated manufacturing platform, comprising:
a work table comprising a tooling mount upon a gantry having at least six axes of movement;
a plurality of tools automatically interfaceable to the tooling mount for interaction with an input one of a work item on a vacuum base of said work table in accordance with a location along the axes of the gantry, comprising at least;
a printer for printing electronics;
a three dimensional thermoplastic printer; and
a precision machining tool;
a computing device, the computing device having a single interface and software for controlling and automating ones of the plurality of tools obtained to the tooling mount, and for controlling the gantry along the at least six axes of movement, to thereby provide an output one of the work item having an integrated fabrication of processes indicated by each of the plurality of tools.

2. The single integrated manufacturing platform of claim 1, wherein the electronics comprise microscale electronics.

3. The single integrated manufacturing platform of claim 2, wherein the electronics comprise nanoscale electronics.

4. The single integrated manufacturing platform of claim 1, wherein the electronics comprise electromechanical electronics.

5. The single integrated manufacturing platform of claim 1, wherein the work item comprises a caseless munition.

6. The single integrated manufacturing platform of claim 1, wherein said plurality of tools further comprises at least one low melt metal casting for controlling and automating by said computing device.

7. The single integrated manufacturing platform of claim 1, wherein the at least six axes of movement comprise at least robotic automiation of the gantry.

8. The single integrated manufacturing platform of claim 1, wherein said gantry comprises a multi-tool turret for the six axes of movement.

9. The single integrated manufacturing platform of claim 8, wherein said work table further comprises gas inlets and outlets.

10. The single integrated manufacturing platform of claim 1, wherein the electronics printer comprises a nanoprinthead.

11. The single integrated manufacturing platform of claim 9, wherein said gas inlets and outlets at least partially comprise a vacuum chamber.

12. The single integrated manufacturing platform of claim 1, wherein at least the precision machine tools are sterile.

13. The single integrated manufacturing platform of claim 1, wherein said work table further comprises remote visual monitoring.

14. The single integrated manufacturing platform of claim 1, wherein said computing device is remotely networked,

15. The single integrated manufacturing platform of claim 1, wherein the at least six axes comprise rotary axes.

16. The single integrated manufacturing platform of claim 1, wherein the electronic printer comprises a Cartesian axis pattern of the at least six axes.

17. The single integrated manufacturing platform of claim 1, wherein the precision tools comprise a resolution in the range of 0.002 to 0.004 mm.
